(19) United States
(12) Patent Application Publication
(10) Pub. No.: US 2010/0195304 A1
(43) Pub. Date: Aug. 5, 2010

(54) PRINTED CIRCUIT BOARD UNIT AND ELECTRONIC APPARATUS

(75) Inventor: Kazuaki TAKAO, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/759,240

(22) Filed: Apr. 13, 2010

Related U.S. Application Data
(63) Continuation of application No. PCT/JP2007/070109, filed on Oct. 15, 2007.

(51) Int. Cl. H05K 1/14

(52) U.S. Cl. 361/804

(57) ABSTRACT

A printed circuit board unit includes a printed wiring board. A socket supports one end of a module substrate. A fixation member is spaced from the socket at a predetermined distance. A movable member is connected to the fixation member for relative horizontal movement in parallel with the surface of the printed wiring board. The movable member receives the other end of the module substrate. A first restriction member is connected to the movable member. The first restriction member is configured to restrict horizontal movement of the module substrate in parallel with the surface of the printed wiring board. A second restriction member connected to the movable member. The second restriction member is configured to restrict perpendicular movement of the module substrate in the direction perpendicular to the surface of the printed wiring board.

### CROSS-REFERENCE TO RELATED APPLICATION

This application is a continuing application, filed under 35 U.S.C. §111(a), of International Application PCT/JP2007/070109, filed on Oct. 15, 2007, the contents of which are incorporated herein by reference.

### FIELD

The present invention relates to a printed circuit board unit on which an expansion card such as a PCI-Express Mini Card is mounted.

### BACKGROUND

An expansion card such as a PCI-Express Mini Card is incorporated in a notebook personal computer. The expansion card is assembled in a motherboard. The motherboard includes a printed wiring board. A socket and a fixation member are mounted on the printed wiring board. The fixation member is spaced from the socket at a predetermined distance. One end of the expansion card is held on the socket. The other end of the expansion card is held on the fixation member. In this manner, the expansion card is electrically connected to the printed wiring board.

The fixation member includes a base immobilized on the printed wiring board. The expansion card is received on the base. A claw member is coupled to the base. The claw member is configured to move in a horizontal direction between a reference position and a withdrawing position. When the claw member is positioned at the reference position, the claw member enters a space right on the expansion card. When the claw member is positioned at the withdrawing position, the claw member withdraws from the space. The claw member at the reference position serves to hold the expansion card on the base. An elastic member is coupled to the base. The elastic member is configured to exhibit an elastic force urging the claw member toward the reference position. The expansion card is removably mounted on the printed wiring board with the assistance of the claw member.

### Publication 1: Japanese Patent Application Laid-open No. 2001-076782

### Publication 2: Japanese Patent Pre-grant Publication No. 7-048393

### Publication 3: Japanese Patent Application Laid-open No. 2005-032446

The socket and the fixation member are sometimes fixed on the printed wiring board at positions shifted from the designed positions so that the relative position between the socket and the fixation member deviates from the designed one. If the interval between the socket and the fixation member is larger than a predetermined interval, the claw member cannot sufficiently enter the space right on the expansion card. As a result, even when a small impact is applied to the motherboard, the expansion card easily separates from the printed wiring board. Accordingly, what is required is means for reliably fixing the expansion card to the printed wiring board.

### SUMMARY

According to a first aspect of the invention, a printed circuit board unit includes: a printed wiring board; a socket mounted on the surface of the printed wiring board, the socket supporting one end of a module substrate; a fixation member fixed to the surface of the printed wiring board, the fixation member spaced from the socket at a predetermined distance; a movable member connected to the fixation member for relative horizontal movement in parallel with the surface of the printed wiring board, the movable member receiving the other end of the module substrate; a first restriction member connected to the movable member, the first restriction member received in a through hole of the module substrate, the first restriction member configured to restrict horizontal movement of the module substrate in parallel with the surface of the printed wiring board; and a second restriction member connected to the movable member, the second restriction member covering over the module substrate, the second restriction member configured to restrict perpendicular movement of the module substrate in the direction perpendicular to the surface of the printed wiring board.

According to a second aspect of the invention, a printed circuit board unit includes: a printed wiring board; a socket mounted on the surface of the printed wiring board, the socket supporting one end of a module substrate; a fixation mechanism fixed to the surface of the printed wiring board at a position spaced from the socket at a predetermined distance, the fixation mechanism supporting the other end of the module substrate; a slot defined in the socket, the slot receiving the one end of the module substrate; and an inner wall surface defined inside the socket, the inner wall surface defining a predetermined gap between the inner wall surface itself and the one end of the module substrate inserted through the slot.

The object and advantages of the embodiments will be realized and attained by means of the elements and combinations particularly pointed out in the appended claims. It is to be understood that both the foregoing general description and the following detailed description are exemplary and explanatory and are not restrictive of the embodiments, as claimed.

### BRIEF DESCRIPTION OF THE DRAWINGS

FIG. 1 is a perspective view schematically illustrating a notebook personal computer as a specific example of the present invention;

FIG. 2 is a perspective view schematically illustrating a printed circuit board unit, namely a motherboard, according to a first embodiment of the present invention;

FIG. 3 is an enlarged partial plan view schematically illustrating a fixation mechanism;

FIG. 4 is a partial sectional view taken along the line 4-4 in FIG. 3;

FIG. 5 is a partial sectional view taken along the line 5-5 in FIG. 3;

FIG. 6 is an enlarged partial sectional view schematically illustrating a socket;

FIG. 7 is a perspective view schematically illustrating the situation where a module substrate in an inclined attitude is inserted into the socket;

FIG. 8 is an enlarged partial sectional view schematically illustrating the situation where the module substrate in the inclined attitude is inserted into the socket;

FIG. 9 is an enlarged partial sectional view schematically illustrating the situation where the module substrate is set on the fixation mechanism;

FIG. 10 is an enlarged partial sectional view schematically illustrating the situation where the module substrate is set on the fixation mechanism;

FIG. 11 is a perspective view schematically illustrating a motherboard according to a second embodiment of the present invention;

FIG. 12 is an enlarged partial plan view schematically illustrating a fixation mechanism;

FIG. 13 is a partial sectional view taken along the line 13-13 in FIG. 12;

FIG. 14 is an enlarged partial sectional view schematically illustrating the situation where a module substrate is set on the fixation mechanism;

FIG. 15 is an enlarged partial sectional view schematically illustrating the situation where the module substrate is set on the fixation mechanism;

FIG. 16 is an enlarged partial sectional view schematically illustrating the situation where the module substrate is set on the fixation mechanism;

FIG. 17 is a perspective view schematically illustrating a motherboard according to a modification of the second embodiment of the present invention;

FIG. 18 is an enlarged partial plan view schematically illustrating a fixation mechanism;

FIG. 19 is a partial sectional view taken along the line 19-19 in FIG. 18;

FIG. 20 is an enlarged partial sectional view schematically illustrating the situation where a module substrate is set on the fixation mechanism;

FIG. 21 is an enlarged partial sectional view schematically illustrating the situation where the module substrate is set on the fixation mechanism;

FIG. 22 is a perspective view schematically illustrating a motherboard according to a third embodiment of the present invention;

FIG. 23 is an enlarged partial sectional view schematically illustrating a socket; and

FIG. 24 is an enlarged partial sectional view schematically illustrating the situation where a module substrate is inserted into the socket.

### DESCRIPTION OF EMBODIMENTS

Description will be made below on an embodiment of the present invention with reference to the attached drawings.

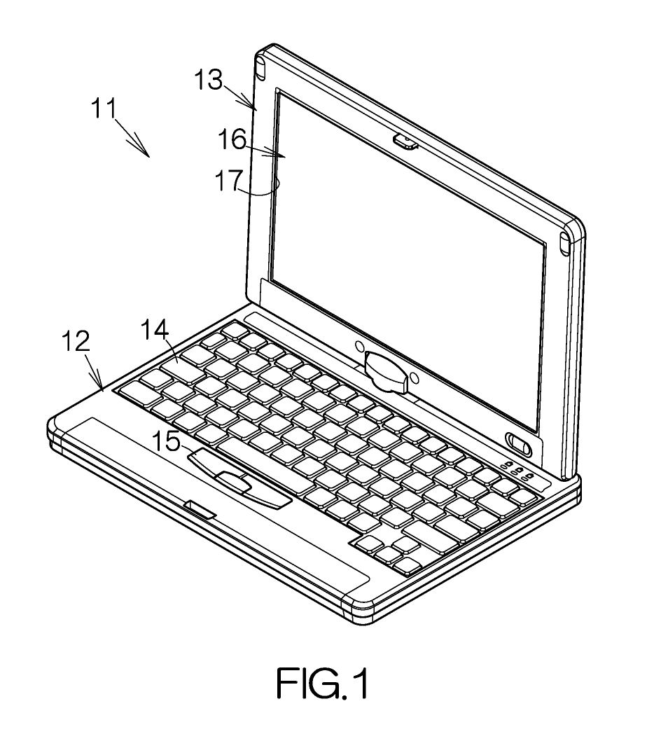

FIG. 1 schematically illustrates a notebook personal computer 11 as a specific example of an electronic apparatus according to the present invention. The notebook personal computer 11 includes a thin or flat main enclosure 12 and a flat display enclosure 13. The flat display enclosure 13 is coupled to the flat main enclosure 12 for relative swinging or pivotal movement. Input devices such as a keyboard 14 and input pads 15 are embedded in the surface of the flat main enclosure 12. Users are allowed to manipulate the keyboard 14 and the input pads 15 to input commands and data.

A printed circuit board unit, namely a motherboard, is enclosed in the flat main enclosure 12, for example. The motherboard will be described later in detail. A large-scale integrated circuit (LSI) chip package, a main memory, and the like, are mounted on the motherboard. The LSI chip package is configured to execute various kinds of processing based on a software program and data temporarily held in the main memory, for example. The software program and the data may be stored in a large capacity storage, such as a hard disk drive, HDD, likewise enclosed in the flat main enclosure 12.

A liquid crystal display (LCD) panel module 16 is incorporated in the flat display enclosure 13, for example. The screen of the LCD panel module 16 gets exposed in a window opening 17 defined in the flat display enclosure 13. Text and graphics appear on the screen. Users can see the ongoing operation of the notebook personal computer 11 based on the appearing text and graphics. The flat display enclosure 13 can be superposed on the flat main enclosure 12 through the pivotal movement relative to the flat main enclosure 12.

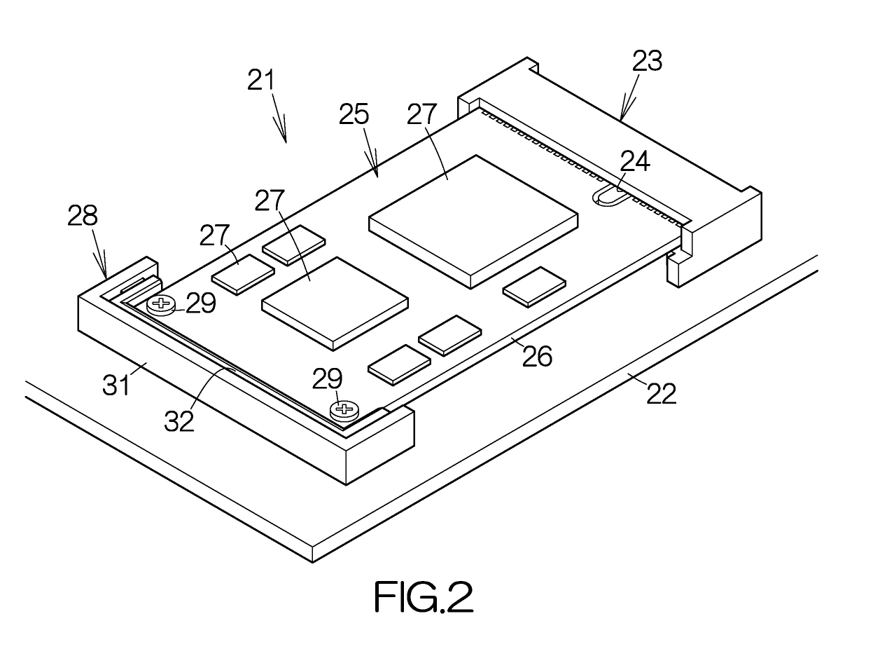

FIG. 2 schematically illustrates a motherboard 21 according to a first embodiment of the present invention. The motherboard 21 includes a printed wiring board 22. A resin substrate is employed for the printed wiring board 22. A socket 23 is rigidly mounted on the surface of the printed wiring board 22. A slot 24 is defined in the front end of the socket 23. The slot 24 extends in the horizontal direction along the surface of the printed wiring board 22. One end or a first end of an expansion card 25 such as a PCI-Express Mini Card is inserted in the slot 24. The first end of the expansion card 25 is in this manner supported on the socket 23.

The expansion card 25 can be any one of a wireless local area network (LAN) card, a memory card, and the like. The expansion card 25 includes a module substrate 26 and electronic components 27, such as LSI chips, mounted on the upper surface of the module substrate 26. The module substrate 26 has a rectangular contour. Electrically-conductive terminals are arranged along the outer periphery of the module substrate 26 at one of the short sides, namely a first end of the module substrate 26, as described later. The electrically conductive terminals are connected to electrically conductive terminals inside the socket 23, respectively. The expansion card 25 is in this manner electrically connected to the printed wiring board 22. The function of the notebook personal computer 11 is thus expanded.

A fixation mechanism 28 is rigidly mounted on the surface of the printed wiring board 22 at a position spaced from the socket 23 at a predetermined distance. The fixation mechanism 28 has one end facing to the slot 24 of the socket 23. The other end or a second end of the expansion card 25 is fixed to the fixation mechanism 28. A pair of screws 29, 29 is utilized to fix the expansion card 25, for example. The screws 29 are screwed into the fixation mechanism 28. The rotation axes of the screws 29 are set in the perpendicular direction perpendicular to the surface of the printed wiring board 22. The screws 29 serve to reliably immobilize the expansion card 25 on the printed wiring board 22. The expansion card 25 is reliably prevented from falling off the printed wiring board 22.

The fixation mechanism 28 includes a fixation member, namely a base 31, immobilized on the surface of the printed wiring board 22. The base 31 extends in parallel with the slot 24 of the socket 23. The fixation mechanism 28 includes a movable member 32 located inside the base 31. The other of the short sides, namely a second end of the module substrate 26 is placed on the movable member 32. The module substrate 26 is received on the bottom plate of the movable member 32. The movable member 32 is coupled to the base 31 for relative horizontal movement along the surface of the printed wiring board 22, as described later. The base 31 may be made of a metallic material, for example. The movable member 32 may be made of a resin material, for example. Molding process may be employed to form the movable member 32, for example.

As illustrated in FIG. 3, the base 31 includes a rear wall 31a standing upright from the bottom plate of the base 31 along the rear end of the base 31. The inner wall surface of the rear wall 31a is opposed to the outer wall surface of a rear wall 32a standing upright from the bottom plate of the movable member 32 along the rear end of the movable member 32. A pair of elastic members, namely leaf springs 33, 33, is attached to the inner wall surface of the rear wall 31a, for example. The leaf springs 33 receive the outer wall surface of the rear wall 32a. The elastic forces of the leaf springs 33, 33 are set equal to each other.

The base 31 also includes a pair of side walls 31b, 31b standing upright from the bottom plate. The inner wall surfaces of the side walls 31b are opposed to the outer wall surfaces of side walls 32b standing upright from the bottom plate of the movable member 32, respectively. An elastic member, namely a leaf spring 34, is attached to the inner wall surface of the individual side wall 31b. The leaf spring 34 receives the outer wall surface of the side wall 32b. The elastic forces of the leaf springs 34, 34 are set equal to each other.

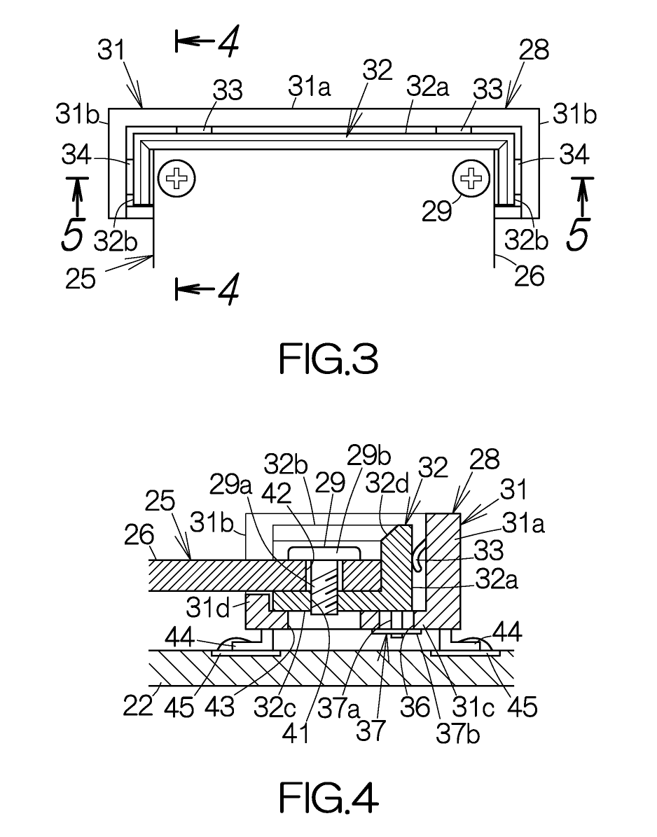

As illustrated in FIG. 4, the bottom plate 32c of the movable member 32 is received on the bottom plate 31c of the base 31. The leaf springs 33 serve to allow the rear wall 32a of the movable member 32 to contact the inner wall surface with the outer periphery of the module substrate 26. A through hole 36 is formed in the bottom plate 31c of the base 31. The through hole 36 receives insertion of a connecting member 37 attached to the movable member 32. The connecting member 37 includes a shaft 37a located in the through hole 36. The shaft 37a extends in the perpendicular direction perpendicular to the surface of the printed wiring board 22. The through hole 36 has a diameter sufficiently larger than that of the shaft 37a. A plate 37b is fixed to the tip or lower end of the shaft 37a. The plate 37b extends wider than the through hole 36 along the lower surface of the bottom plate 31c. In this manner, the base 31 is connected to the movable member 32 via the connecting member 37.

The movable member 32 is configured to move in the horizontal direction along the upper surface of the bottom plate 31c of the base 31 in parallel with the surface of the printed wiring board 22, as described above. The horizontal movement of the movable member 32 enables the movement of the shaft 37a inside the through hole 36. Since the diameter of the through hole 36 is sufficiently larger than that of the shaft 37a, the shaft 37a is allowed to move inside the through hole 36 over a predetermined range. Likewise, the plate 37b is allowed to move in the horizontal direction along the lower surface of the bottom plate 31c. The connecting member 37 may be made of a metallic material, for example. So-called caulking process may be employed to form the connecting member 37, for example.

Screw bores 41 are formed in the bottom plate 32c of the movable member 32. Screw shafts 29a of the screws 29 are received in the screw bores 41, respectively. The screw bores 41 are connected to through holes 42 formed in the module substrate 26. The positions of the through holes 42 on the module substrate 26 are determined in accordance with the standards. The screws 29 are screwed into the screw bores 41 through the through holes 42, respectively. Screw heads 29b of the screws 29 are positioned directly on the upper surface of the module substrate 26. As a result, the screw heads 29b serve to restrict the perpendicular movement of the module substrate 26 in the perpendicular direction perpendicular to the surface of the printed wiring board 22. The screw shafts 29a serve to restrict the horizontal movement of the module substrate 26 in the horizontal direction.

When the screws 29 are sufficiently screwed into the screw bores 41, the tip ends of the screw shafts 29a project from the ends of the screw bores 41, for example. The screw shafts 29a are thus received in receiving holes 43 formed in the bottom plate 31c of the base 31, respectively. The receiving holes 43 have the diameter sufficiently larger than that of the screw shafts 29a. Consequently, even though the movable member 32 moves in the horizontal direction as described later, the screws 29 are prevented from interfering with the base plate 31c of the base 31. Here, the screw shaft 29a of the screw 29 serves as a first restriction member according to a specific embodiment of the present invention. The screw head 29b of the screw 29 serves as a second restriction member according to a specific embodiment of the present invention.

A front wall 31d is formed on the base 31 at the front end of the base 31. The front wall 31d stands upright from the bottom plate 31c. The interval between the front wall 31d and the rear wall 31a is set larger than the entire length of the movable member 32 from its front end to the rear end. The rear wall 32a of the movable member 32 defines an inclined surface 32d at the top of the rear wall 32a. The inclined surface 32d is connected to the inner wall surface of the rear wall 32a. The inclined surface 32d gets farther from the surface of the module substrate 26 as the position gets farther outward in the horizontal direction from the contour of the module substrate 26. A pair of electrically conductive terminals 44, 44 is formed integral with the base 31, for example. The electrically conductive terminals 44 are soldered on pads 45 formed on the surface of the printed wiring board 22. In this manner, the fixation mechanism 28 is fixed on the surface of the printed wiring board 22.

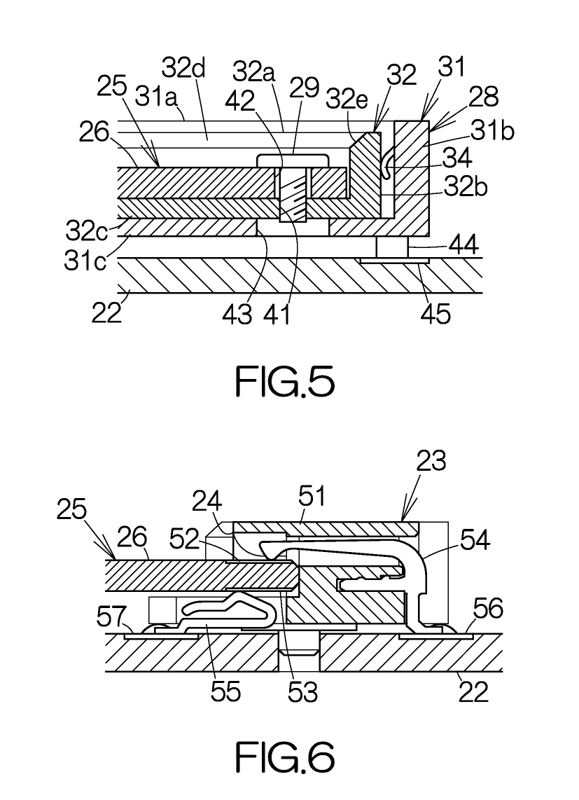

As illustrated in FIG. 5, the movable member 32 defines an inclined surface 32e on the top of the individual side wall 32b. The individual inclined surface 32e is connected to the inner wall surface of the corresponding side wall 32b. The inclined surface 32e gets farther from the surface of the module substrate 26 as the position gets farther outward in the horizontal direction from the contour of the module substrate 26. The inclined surface 32e may be connected to the inclined surface 32d at a joint between the side wall 32b and the rear wall 32a. The inclination angle of the inclined surface 32e relative to a horizontal plane may be set equal to that of the inclined surface 32d relative to the horizontal plane.

As illustrated in FIG. 6, the socket 23 includes a socket body 51 in the shape of a rectangular parallelepiped, for example. The socket body 51 is made of a resin material, for example. Molding process may be employed in this case. The aforementioned slot 24 is formed in the front of the socket body 51. The first end of the module substrate 26 is received in the socket body 51 through the slot 24. Front-side electrically conductive terminals 52 are formed on the front surface of the module substrate 26 along the outer periphery of the module substrate 26 at the short side of the module substrate 26. Likewise, back-side electrically conductive terminals 53 are formed on the back surface of the module substrate 26 along the outer periphery of the module substrate 26 at the short side of the module substrate 26. The front-side and back-side electrically conductive terminals 52, 53 are connected to the aforementioned electronic components 27.

The socket 23 includes first electrically conductive terminals 54 rigidly fixed to the socket body 51. Second electrically conductive terminals 55 are rigidly fixed to the socket body 51. The individual first electrically conductive terminal 54 exhibits an elastic force to urge one end of the first electrically conductive terminal 54 against the corresponding front-side electrically conductive terminal 52. The other end of the individual first electrically conductive terminal 54 is soldered to an electrically conductive pad 56 on the printed wiring board 22. The individual second electrically conductive terminal 55 exhibits an elastic force to urge one end of the second electrically conductive terminal 55 against the back-side electrically conductive terminal 53. The other end of the individual second electrically conductive terminal 55 is soldered to an electrically conductive pad 57 on the printed wiring board 22. In this manner, the expansion card 25 is electrically connected to the printed wiring board 22.

As is apparent from FIG. 6, the contact point of the first electrically conductive terminals 54 against the module substrate 26 is located closer to the outer periphery of the module substrate 26 than the contact point of the second electrically conductive terminals 55 against the module substrate 26 is. Accordingly, the elastic forces of the first and second electrically conductive terminals 54, 55 always act on the module substrate 26 so as to lift the second end of the module substrate 26 away from the surface of the printed wiring board 22. Since the screws 29 are configured to restrict the perpendicular movement of the module substrate 26 at the second end of the module substrate 26, the module substrate 26 is kept in a horizontal attitude in parallel with the surface of the printed wiring board 22.

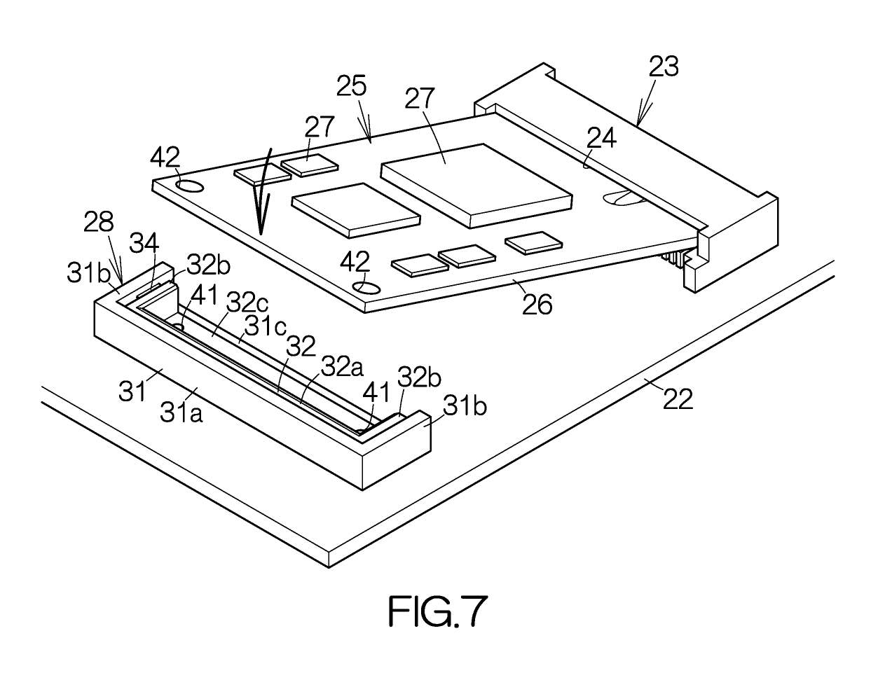

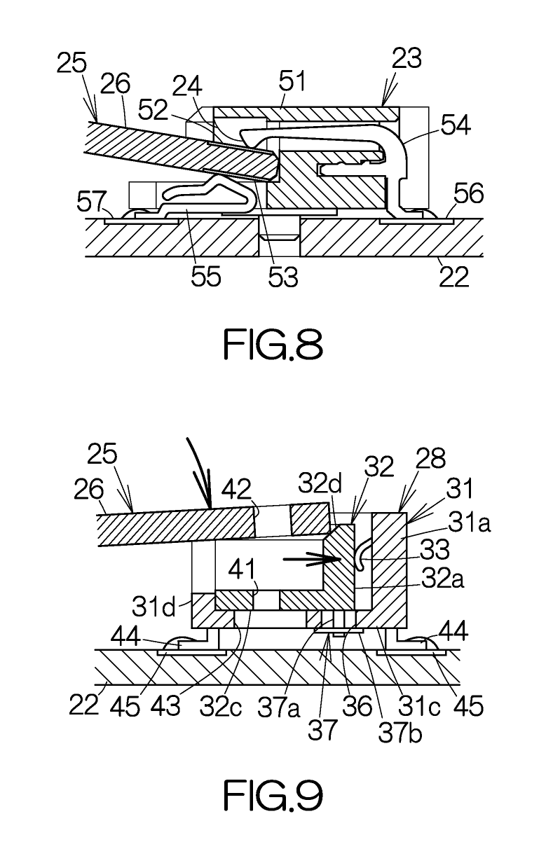

Next, description will be made on a method of making the motherboard 21. The socket 23 and the fixation mechanism 28 have beforehand been fixed on the surface of the printed wiring board 22. As illustrated in FIG. 7, the first end of the module substrate 26 of the expansion card 25 is inserted into the slot 24 of the socket 23. The module substrate 26 is kept in an inclined attitude during the insertion. The first end of the module substrate 26 is held against the inner wall surface of the socket body 51, as illustrated in FIG. 8. When an operator pushes the second end of the expansion card 25 toward the surface of the printed wiring board 22, the module substrate 26 pivotally moves around the first end. The pivotal movement of the module substrate 26 generates elastic deformation of the first and second electrically conductive terminals 54, 55 since the first and second electrically conductive terminals 54, 55 keep contacting with the module substrate 26. The elastic deformation causes accumulation of a resilient force in the first and second electrically conductive terminals 54, 55.

As illustrated in FIG. 9, the leaf springs 33 serve to contact the front end of the movable member 32 against the front wall 31d of the base 31. The movable member 32 is configured to move in the horizontal direction between a front position and a rear position. The movable member 32 takes the front position to contact the front end of the movable member 32 against the front wall 31d. The movable member 32 takes the rear position to get closest to the rear wall 31a of the base 31. Here, the position of the fixation mechanism 28 relative to the socket 23 may be determined with reference to an intermediate position of the movable member 32 between the front position and the rear position. Likewise, the movable member 32 is configured to move in the horizontal direction between a first position and a second position. The movable member 32 takes the first position to get closest to one of the side walls 31b of the base 31. The movable member 32 takes the second position to get closest to the other of the side walls 31b of the base 31. Here, the position of the fixation mechanism 28 relative to the socket 23 may be determined with reference to an intermediate position of the movable member 32 between the first position and the second position.

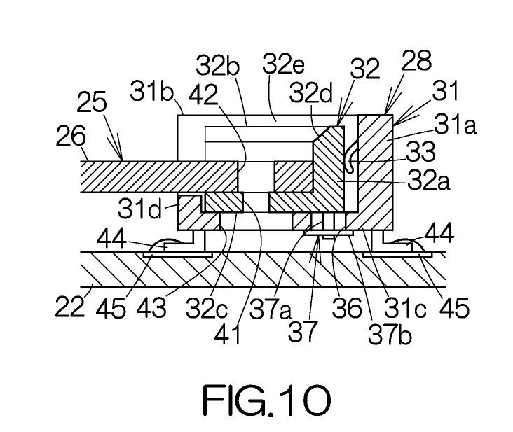

When the operator pushes the second end of the module substrate 26, the module substrate 26 pivotally moves toward the printed wiring board 22 so that the second end of the module substrate 26 is receive on the inclined surface 32d of the movable member 32. As the operator further pushes the second end of the module substrate 26, the second end of the module substrate 26 slides down along the inclined surface 32d. The urging force to pivotally move the module substrate 26 allows the movable member 32 to move in the horizontal direction in parallel with the surface of the printed wiring board 22. The movable member 32 is subjected to the elastic forces of the leaf springs 33. Here, no shift is assumed in the relative position between the socket 23 and the fixation mechanism 28 in the lateral direction of the module substrate 26. The module substrate 26 is thus received on the bottom plate 32c of the movable member 32, as illustrated in FIG. 10. The leaf springs 33 exhibit the elastic force to allow the rear wall 32a of the movable member 32 to receive the outer periphery of the module substrate 26.

In general, a deviation of the distance between the rear wall 32a and the screw bore 41 or between the side walls 32b and the screw bores 41 from the distance between the outer periphery of the module substrate 26 and the through holes 42 is quite smaller than a shift in the relative position between the socket 23 and the fixation mechanism 28. Accordingly, when the module substrate 26 is received on the movable member 32, the through holes 42 of the module substrate 26 are connected to the screw bores 41 of the movable member 32. The screws 29 are then screwed into the screw bores 41 through the through holes 42. The screws 29 serve to restrict the horizontal movement and perpendicular movement of the module substrate 26. In this manner, the module substrate 26 is reliably fixed to the movable member 32, namely the fixation mechanism 28 in a rigid manner.

Assume that a shift is observed in the relative position between the socket 23 and the fixation mechanism 28 in the lateral direction of the module substrate 26. In this case, the module substrate 26 is received not only on the inclined surface 32d of the rear wall 32a but also on the inclined surface 32e of either one of the side walls 32b. As the operator pushes, the second end of the module substrate 26 slides down on the inclined surface 32e. The urging force to pivotally move the module substrate 26 allows the movable member 32 to move in the horizontal direction in parallel with the surface of the printed wiring board 22. The module substrate 26 is received on the bottom plate 32c of the movable member 32 in the same manner as described above. Either one of the side walls 31b receives the outer periphery of the module substrate 26 based on the elastic force of the leaf spring 34.

The first end of the module substrate 26 is supported on the socket 23 when the expansion card 25 is to be set on the motherboard 21. The second end of the module substrate 26 is rigidly fixed to the fixation mechanism 28. The movable member 32 is connected to the base 31 for relative horizontal movement in parallel with the surface of the printed wiring board 22. As a result, even if the relative position between the socket 23 and the fixation mechanism 28 shifts from the designed relative position, the horizontal movement of the movable member 32 enables a reliable rigid fixation of the module substrate 26 to the movable member 32. A shift can be acceptable in the relative position between the socket 23 and the fixation mechanism 28. Additionally, the screws 29 are utilized to rigidly fix the module substrate 26 to the movable member 32. The module substrate 26 is reliably prevented from falling off.

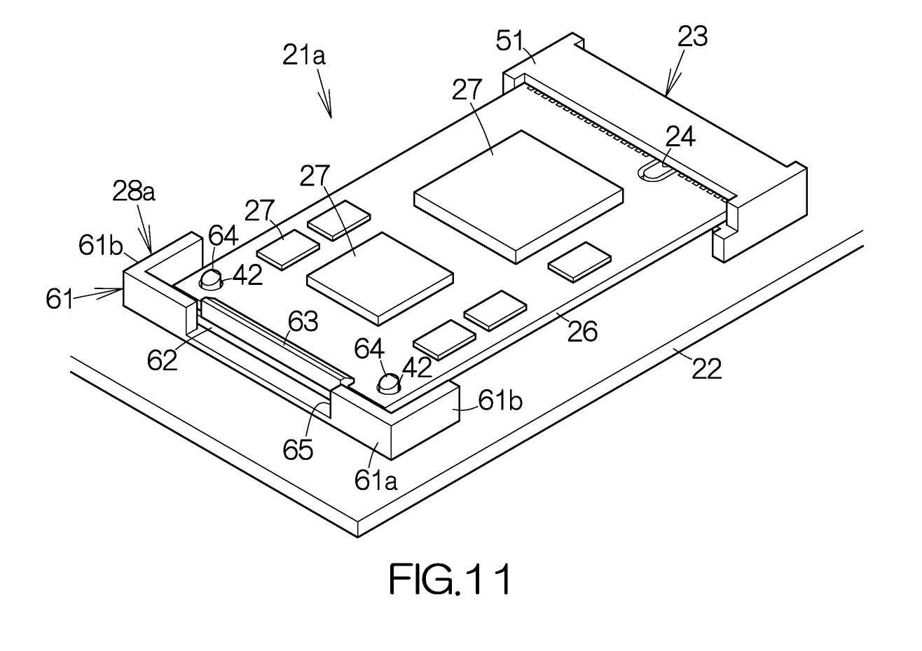

FIG. 11 schematically illustrates a motherboard 21a according to a second embodiment of the present invention. A fixation mechanism 28a is incorporated in the motherboard 21a in place of the aforementioned fixation mechanism 28. The fixation mechanism 28a includes a base 61 mounted on the surface of the printed wiring board 22. The base 61 extends in parallel with the slot 24 of the socket 23. The base 61 is made of a metallic material, for example. The base 61 is fixed to the surface of the printed wiring board 22 through the electrically conductive terminals 44 in the same manner as the base 31. The base 61 includes a rear wall 61a. A recess 65 is formed in the rear wall 61a. The rear wall 61a is connected to a pair of side walls 61b, 61b opposed to each other.

A movable member 62 in the shape of a plate is located inside the base 61, for example. The movable member 62 is received on the bottom plate of the base 61. The movable member 62 is connected to the base 61 for relative horizontal movement in parallel with the surface of the printed wiring board 22 as described later. An engagement member 63 is coupled to the movable member 62. The module substrate 26 is placed in a space between the engagement member 63 and the movable member 62. The engagement member 63 extends inward from the contour of the module substrate 26 in parallel with the surface of the movable member 63. Simultaneously, the module substrate 26 is placed in a space between the engagement member 63 and the socket 23. The through holes 42 of the module substrate 26 receive protrusions 64 standing upright from the bottom plate of the movable member 62, respectively. The movable member 62 and the engagement member 63 are made of a resin material, for example. Molding process may be employed to form the movable member 62 and the engagement member 63, for example.

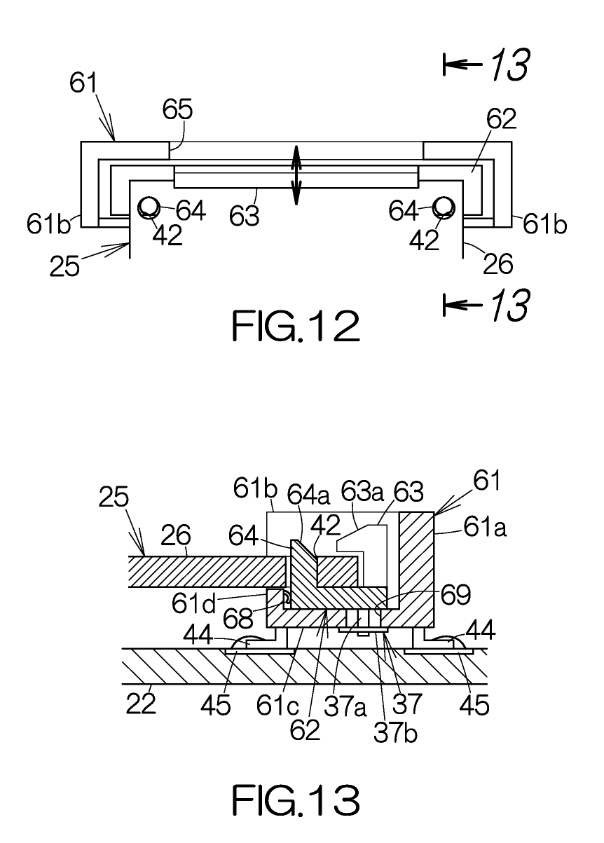

As illustrated in FIG. 12, the engagement member 63 has the width smaller than the width of the recess 65. The width of the engagement member 63 is defined along the rear end of the movable member 62. The width of the recess 65 is defined along the rear end of the base 61. The engagement member 63 is configured to horizontally move relative to the movable member 62 in parallel with the long sides of the module substrate 26. The engagement member 63 is received in a guiding groove, not illustrated, formed in the movable member 62 for the horizontal movement, for example. A coil spring, not illustrated, is coupled to the engagement member 63, for example. As the engagement member 63 horizontally moves in a direction away from the socket 23, an elastic or resilient force is accumulated in the coil spring.

As illustrated in FIG. 13, an inclined surface 63a is defined on the top of the engagement member 63. The inclined surface 63a gets farther from the surface of the module substrate 26 as the position gets farther in the horizontal direction outward from the contour of the module substrate 26. A front wall 61d is defined in the front of the base 61. The front wall 61d stands upright from the bottom plate 61c of the base 61. An elastic member, namely a leaf spring 68, is attached to the inner wall surface of the front wall 61d. The leaf spring 68 receives the front end of the movable member 62. The aforementioned connecting member 37 is attached to the bottom surface of the movable member 62. The connecting member 37 is received in a through hole 69 formed in the bottom plate 61c of the base 61.

The individual protrusion 64 is formed in the shape of a cylinder, for example. The protrusions 64 are formed integral with the bottom plate of the movable member 62. Here, the protrusions 64 may be arranged along the front end of the movable member 62. An inclined surface 64a is defined on the tip end of the individual protrusion 64. The inclined surface 64a gets farther from the surface of the bottom plate of the movable member 62 as the position gets farther in the horizontal direction from the engagement member 63 toward the socket 23. The protrusion 64 serves as a first restriction member according to a specific embodiment of the present invention. The engagement member 63 serves as a second restriction member according to a specific embodiment of the present invention. Like reference numerals are attached to the structure or components equivalent to those of the aforementioned motherboard 21.

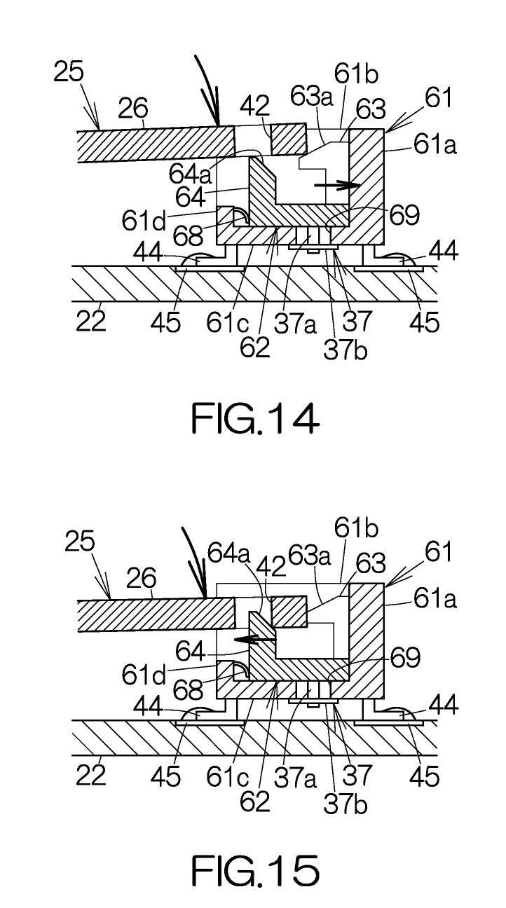

The socket 23 and the fixation mechanism 28a have beforehand been fixed to the surface of the printed wiring board 22 in the same manner as described above for the production of the motherboard 21a. The module substrate 26 of the expansion card 25 is inserted into the slot 24 of the socket 23. The module substrate 26 is kept in an inclined attitude during the insertion. As illustrated in FIG. 14, the leaf spring 68 serves to contact the rear end of the movable member 62 against the rear wall 61a of the base 61. The movable member 62 is configured to horizontally move between a front position and a rear position. The movable member 62 takes the front position to get closest to the front wall 61d of the base 61. The movable member 62 takes the rear position to get received on the rear wall 61a of the base 61. Here, the position of the fixation mechanism 28a relative to the socket 23 may be determined with reference to an intermediate position of the movable member 62 between the front position and the rear position.

As is apparent from FIG. 14, when an operator pushes the second end of the module substrate 26, the module substrate 26 pivotally moves toward the printed wiring board 22 so that the second end of the module substrate 26 is received on the inclined surface 63a of the engagement member 63. As the operator further pushes the second end of the module substrate 26, the second end of the module substrate 26 slides down along the inclined surface 63a. The urging force to pivotally move the module substrate 26 allows the engagement member 63 to move in the horizontal direction in parallel with the surface of the printed wiring board 22. The engagement member 63 is thus allowed to move toward the recess 65. As illustrated in FIG. 15, when the second end of the module substrate 26 gets off the inclined surface 63a, the second end of the module substrate 26 is received on the front end of the engagement member 63. The engagement member 63 gets farthest from the protrusions 64.

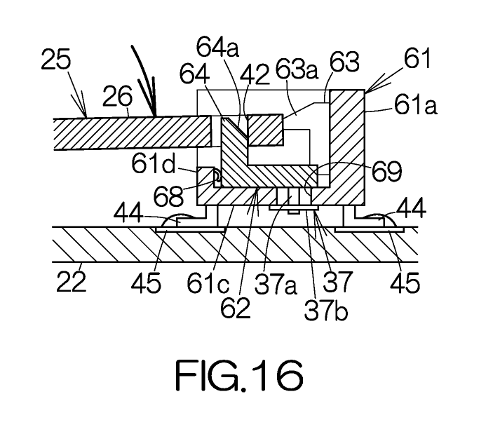

The inclined surfaces 64a of the protrusions 64 then receive the module substrate 26 at the edges defining the contours of the through holes 42, respectively. Since the inclined surfaces 64 get farther from the surface of the movable member 62 as the position gets farther in the horizontal direction from the engagement member 63 toward the socket 23, the urging force to pivotally move the module substrate 26 thus allows the movable member 62 to horizontally move with the assistance of the inclined surfaces 64a. In this manner, as illustrated in FIG. 16, the protrusions 64 are progressively inserted into the through holes 42, respectively. The module substrate 26 is eventually received on the bottom plate 62c of the movable member 62. When the module substrate 26 is released from the contact with the engagement member 63, the resilient force of the coil spring forces the engagement member 63 to return to the original position so that the module substrate 26 is placed in a space between the engagement member 63 and the movable member 62.

The first end of the module substrate 26 is supported on the socket 23 when the expansion card 25 is to be set on the motherboard 21a. The second end of the module substrate 26 is supported on the fixation mechanism 28a. Specifically, the module substrate 26 is supported on the movable member 62 and the engagement member 63. The movable member 62 is connected to the base 61 for relative horizontal movement in parallel with the surface of the printed wiring board 22. Accordingly, even if the relative position between the socket 23 and the fixation mechanism 28a shifts from the designed relative position, the horizontal movement of the movable member 62 enables a reliable rigid fixation of the module substrate 26 to the movable member 62. A shift can be acceptable in the relative position between the socket 23 and the fixation mechanism 28a.

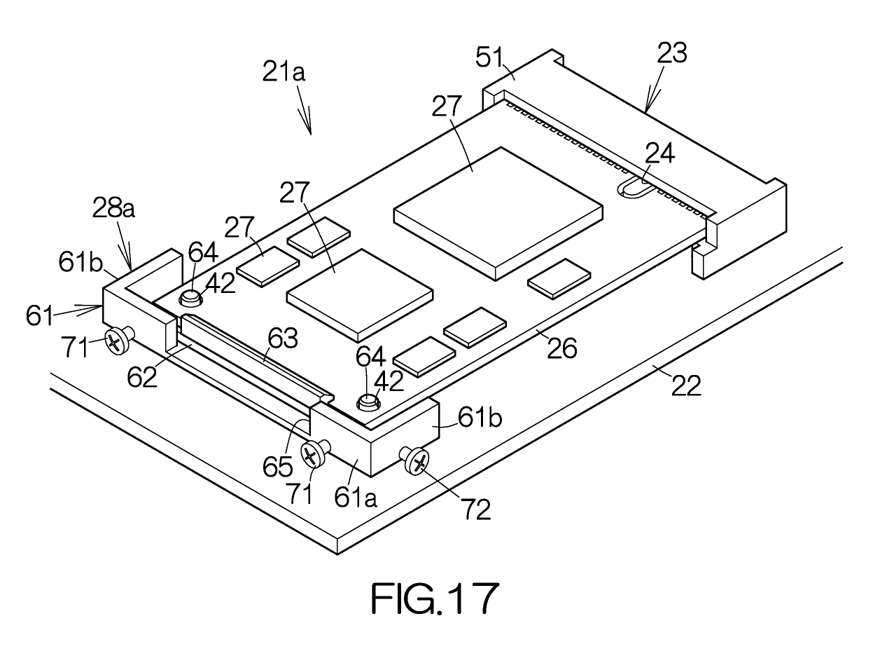

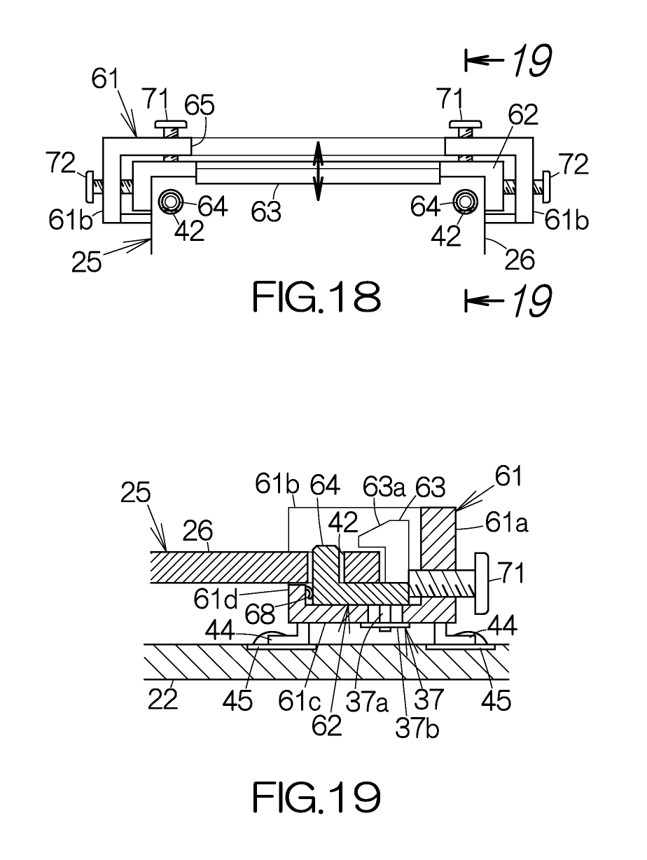

As illustrated in FIG. 17, screws 71, 72 may be screwed into the base 61 in the motherboard 21a according to the second embodiment. The screws 71, 71 in a pair are screwed into the rear wall 61a at positions off the recess 65. The screws 71 have the longitudinal axes extending in parallel with the surface of the printed wiring board 22, respectively. Referring also to FIG. 18, the tip ends of the screws 71 are received on the rear end of the movable member 62. The screws 72 are screwed into the side walls 61b, respectively. The screws 72 have the longitudinal axes extending in parallel with the surface of the printed wiring board 22. The tip ends of the screws 72 are received on the side ends of the movable member 62, respectively. The direction of the longitudinal axes of the screws 71 intersects at right angles with that of the longitudinal axes of the screws 72. The screws 72, 72 are arranged on one straight line intersecting at right angles with the end surfaces of the long sides of the module substrate 26. As illustrated in FIG. 19, the tip end of the individual protrusion 64 defines a flattened surface extending in parallel with the surface of the movable member 62. The formation of the inclined surface 64a is omitted in the individual protrusion 64. Like reference numerals are attached to the structure or components equivalent to those of the aforementioned motherboard 21.

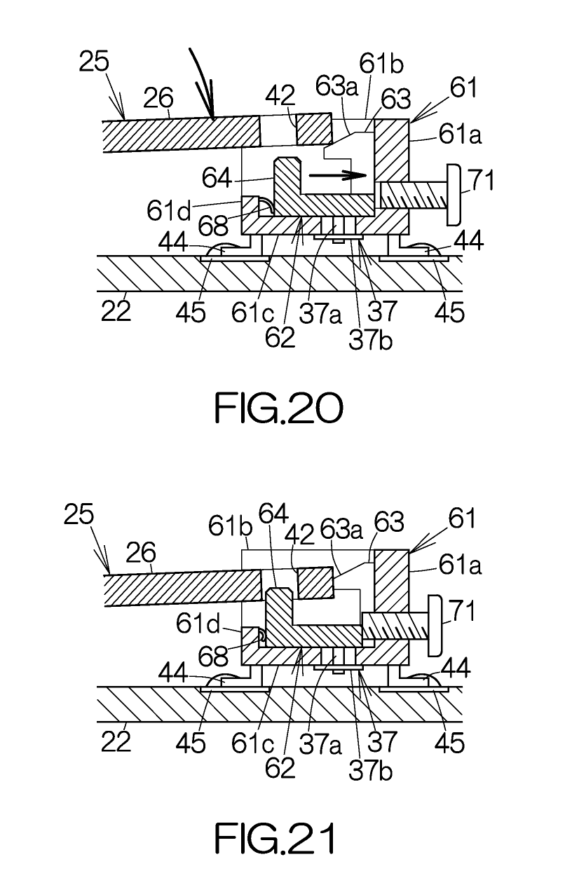

The socket 23 and the fixation mechanism 28a have beforehand been fixed to the surface of the printed wiring board 22 in the same manner as described above for the production of the motherboard 21a. The module substrate 26 of the expansion card 25 is inserted into the slot 24 of the socket 23. The module substrate 26 is kept in an inclined attitude during the insertion. As illustrated in FIG. 20, the module substrate 26 pivotally moves, so that the second end of the module substrate 26 is received on the inclined surface 63a of the engagement member 63. As the operator further pushes the second end of the module substrate 26, the second end of the module substrate 26 slides down along the inclined surface 63a. The engagement member 63 moves in the horizontal direction in parallel with the surface of the printed wiring board 22. The engagement member 63 is thus allowed to move toward the recess 65.

The screwed amounts of the screws 71 and the screws 72 into the base 61 is determined in accordance with the position of the module substrate 26. The axial movement of the screws 71, 72 enables a horizontal movement of the movable member 62 along the surface of the bottom plate 61c of the base 61. In this manner, the position of the movable member 62 can finely be adjusted relative to the base 61. The adjustment serves to align the protrusions 64 with the through holes 42 of the module substrate 26, respectively. As illustrated in FIG. 21, the protrusions 64 are progressively inserted into the through holes 42, respectively. The module substrate 26 is eventually received on the bottom plate 62c of the movable member 62. Since the module substrate 26 is released from the contact with the engagement member 63, the module substrate 26 is placed in a space between the engagement member 63 and the movable member 62.

The first end of the module substrate 26 is supported on the socket 23 when the expansion card 25 is to be set on the motherboard 21a. The second end of the module substrate 26 is supported on the fixation mechanism 28a. Specifically, the module substrate 26 is supported on the movable member 62 and the engagement member 63. The movable member 62 is connected to the base 61 for relative horizontal movement in parallel with the surface of the printed wiring board 22. The screws 71, 72 are related to the movable member 62. The screws 71, 72 are utilized to finely adjust the position of the movable member 62 in the horizontal direction. Consequently, even if the relative position between the socket 23 and the fixation mechanism 28a shifts from the designed relative position, the horizontal movement of the movable member 62 enables a reliable rigid fixation of the module substrate 26 to the movable member 62. A shift can be acceptable in the relative position between the socket 23 and the fixation mechanism 28a.

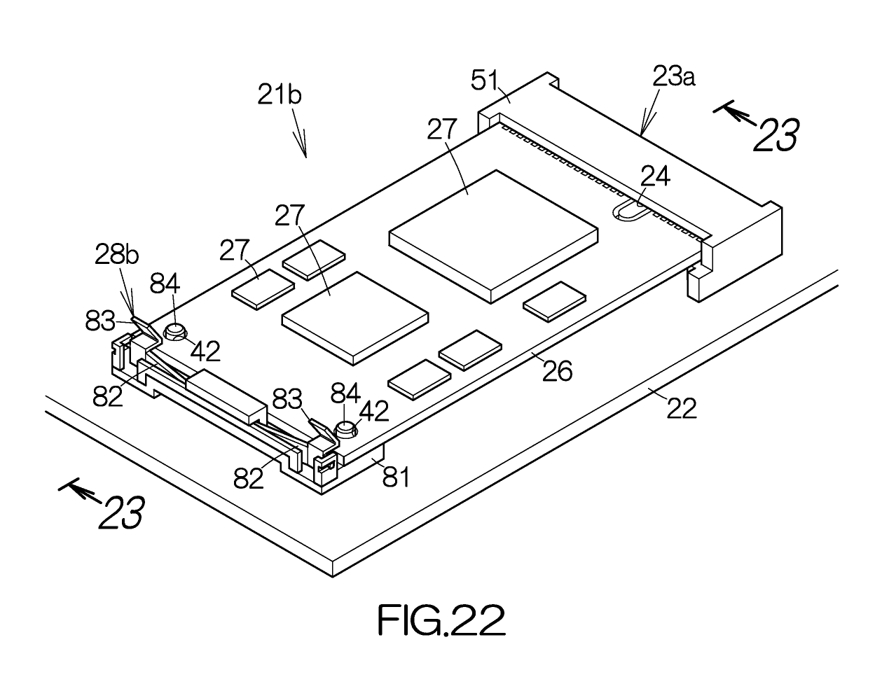

FIG. 22 schematically illustrates a motherboard 21b according to a third embodiment of the present invention. The motherboard 21b includes a socket 23a and a fixation mechanism 28b. The socket 23a and the fixation mechanism 28b are mounted on the printed wiring board 22. A conventional fixation mechanism may be employed as the fixation mechanism 28b. The conventional fixation mechanism 28b includes a base 81 immobilized on the surface of the printed wiring board 22. The base 81 may be made of a resin material, for example. Molding process may be employed to form the base 81, for example. A pair of elastic members, namely leaf springs 82, 82, is attached to the base 81. The leaf springs 82, 82 extend in an upright attitude toward both the sides of the base 81, respectively. The closer the leaf springs 82 are to the sides of the base 81, the closer the leaf springs 82 are to the socket 23a.

A claw member 83 is formed in the tip end of the individual leaf spring 82. The module substrate 26 is placed in a space between the claw members 83 and the base 81. In this case, the claw members 83 are set at reference positions. When the claw members 83 take the reference positions, respectively, the module substrate 26 is held between the base 81 and the claw members 83. The leaf springs 82 allow the claw members 83 to horizontally move outward from the space right on the module substrate 26. The claw members 83 are thus allowed to reach withdrawing positions outside the contour of the module substrate 26, respectively. When the claw members 83 reach the withdrawing positions, the module substrate 26 can be removed from the base 81. The through holes 42 of the module substrate 26 respectively receive protrusions 84 standing upright from the bottom plate 81.

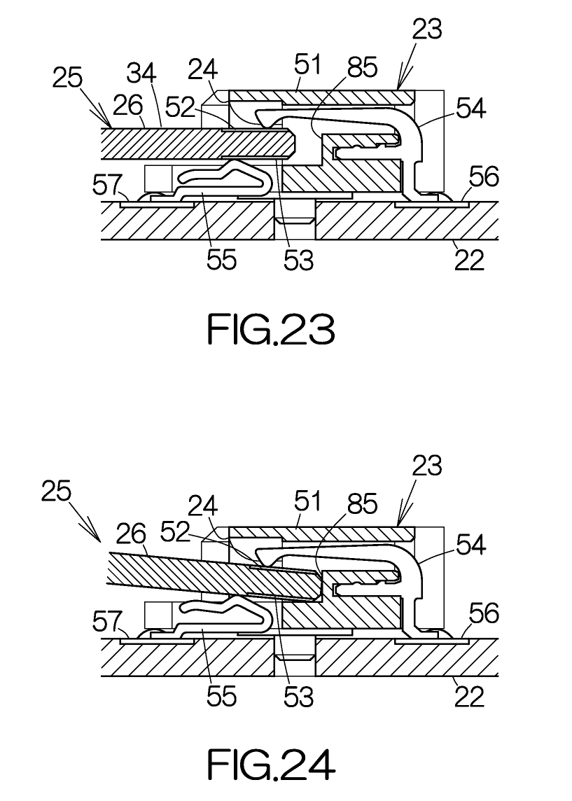

FIG. 23 schematically illustrates the structure of the socket 23a. The socket 23a includes the socket body 51 in the same manner as the socket 23. The socket body 51 defines an inner wall surface 85 opposed to the slot 24. When the second end of the module substrate 26 is set on the fixation mechanism 28b, a predetermined gap is defined between the inner wall surface 85 and the outer periphery of the first end of the module substrate 26. Here, the inner wall surface 85 may extend along a perpendicular plane perpendicular to the surface of the printed wiring board 22. Like reference numerals are attached to the structure or components equivalent to those of the aforementioned motherboards 21, 21a.

The socket 23a and the fixation mechanism 28b have beforehand been fixed on the surface of the printed wiring board 22 for the production of the motherboard 21b. The module substrate 26 of the expansion card 25 is inserted into the slot 24 of the socket 23a in the same manner as described above. The module substrate 26 is kept in an inclined attitude during the insertion. The first end of the module substrate 26 is urged against the inner wall surface 85, as illustrated in FIG. 24. When an operator pushes the second end of the expansion card 25 toward the surface of the printed wiring board 22, the module substrate 26 pivotally moves around the first end.

In this case, the operator aligns the through holes 42 of the module substrate 26 with the protrusions 84 by pivotally moving the module substrate 26. Since the predetermined gap is defined between the inner wall surface 85 and the first end of the module substrate 26 in the set position, the contact of the first end of the module substrate 26 against the inner wall surface 85 allows the module substrate 26 to shift from the set position toward the fixation mechanism 28b. The operator can thus horizontally move the module substrate 26 in parallel with the surface of the printed wiring board 22 so as to position the module substrate 26. The horizontal movement of the module substrate 26 enables alignment of the through holes 42 of the module substrate 26 with the protrusions 84.

When the second end of the module substrate 26 is urged toward the base 81, the module substrate 26 is brought in contact with the claw members 83 so that the claw members 83 are positioned at the withdrawing positions. The protrusions 84 are inserted in the through holes 42 of the module substrate 26, respectively. In this manner, the module substrate 26 is received on the surface of the base 81. Since the module substrate 26 is released from the contact with the claw members 83, the elastic forces of the leaf springs 82 allow the claw members 83 to return to the reference positions. The claw members 83 thus hold the module substrate 26 on the base 81.

The inner wall surface 85 is defined outside the outer periphery of the module substrate 26 in the motherboard 21b. The module substrate 26 can thus be inserted deeper in the socket 23a. In the case where a smaller interval is established between the socket 23a and the fixation mechanism 28b as compared with the designed interval, for example, the module substrate 26 is allowed to horizontally move in accordance with the position of the fixation mechanism 28b so that the module substrate 26 is set on the printed wiring board 22. In this manner, the position of the module substrate 26 is finely adjusted relative to the fixation mechanism 28b. The expansion card 25 is thus reliably set on the printed wiring board 22.

All examples and conditional language recited herein are intended for pedagogical purposes to aid the reader in understanding the invention and the concept contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A printed circuit board unit comprising:
a printed wiring board;
a socket mounted on a surface of the printed wiring board, the socket supporting one end of a module substrate;
a fixation member fixed to the surface of the printed wiring board, the fixation member spaced from the socket at a predetermined distance;
a movable member connected to the fixation member for relative horizontal movement in parallel with the surface of the printed wiring board, the movable member receiving an other end of the module substrate;
a first restriction member connected to the movable member, the first restriction member received in a through hole of the module substrate, the first restriction member configured to restrict horizontal movement of the module substrate in parallel with the surface of the printed wiring board; and
a second restriction member connected to the movable member, the second restriction member covering over the module substrate, the second restriction member configured to restrict perpendicular movement of the module substrate in a direction perpendicular to the surface of the printed wiring board.

2. The printed circuit board unit according to claim 1, wherein the first restriction member is a screw shaft of a screw screwed into a screw bore defined in the movable member while the second restriction member is a screw head of the screw.

3. The printed circuit board unit according to claim 1, wherein the first restriction member is a protrusion defined on the movable member, the protrusion standing upright from a surface of the movable member, and the second restriction member is a claw member coupled to the movable member, the claw member opposed to the surface of the movable member so that the module substrate is positioned therebetween.

4. The printed circuit board unit according to claim 1, further comprising a screw screwed into the fixation member so that the screw is received on a periphery of the movable member, the screw configured to adjust position of the movable member in a horizontal direction parallel to the surface of the printed wiring board.

5. An electronic apparatus comprising:
an enclosure;
a printed wiring board enclosed in the enclosure;
a socket mounted on a surface of the printed wiring board;
a fixation member fixed to the surface of the printed wiring board, the fixation member spaced from the socket at a predetermined distance;
a movable member connected to the fixation member for relative horizontal movement in parallel with the surface of the printed wiring board;
a module substrate having one end supported on the socket and an other end received on the movable member;
a through hole penetrating from a front surface of the module substrate to a back surface of the module substrate;
a first restriction member connected to the movable member, the first restriction member received in the through hole of the module substrate, the first restriction member configured to restrict horizontal movement of the module substrate in parallel with the surface of the printed wiring board; and
a second restriction member connected to the movable member, the second restriction member covering over the module substrate, the second restriction member configured to restrict perpendicular movement of the module substrate in a direction perpendicular to the surface of the printed wiring board.

6. A printed circuit board unit comprising:
a printed wiring board;
a socket mounted on a surface of the printed wiring board, the socket supporting one end of a module substrate;
a fixation mechanism fixed to the surface of the printed wiring board at a position spaced from the socket at a predetermined distance, the fixation mechanism supporting an other end of the module substrate;
a slot defined in the socket, the slot receiving the one end of the module substrate; and
an inner wall surface defined inside the socket, the inner wall surface defining a predetermined gap between the inner wall surface itself and the one end of the module substrate inserted through the slot.

7. An electronic apparatus comprising:
a printed wiring board;
a socket mounted on a surface of the printed wiring board, the socket supporting one end of a module substrate;
a fixation mechanism fixed to the surface of the printed wiring board at a position spaced from the socket at a predetermined distance, the fixation mechanism supporting an other end of the module substrate;
a slot defined in the socket, the slot receiving the one end of the module substrate; and
an inner wall surface defined inside the socket, the inner wall surface defining a predetermined gap between the inner wall surface itself and the one end of the module substrate inserted through the slot.
